(19) United States
(12) Patent Application Publication
(10) Pub. No.: US 2026/0051343 A1
(43) Pub. Date: Feb. 19, 2026

(54) COMPUTE-IN-MEMORY SYSTEMS AND METHODS FOR OPERATING THE SAME

(71) Applicant: Taiwan Semiconductor Manufacturing Company, Ltd., Hsinchu (TW)

(72) Inventors: Hidehiro Fujiwara, Hsinchu City (TW); Haruki Mori, Hsinchu City (TW); Je-Min Hung, Hsinchu City (TW); Brian Crafton, Hsinchu City (TW)

(73) Assignee: Taiwan Semiconductor Manufacturing Company, Ltd., Hsinchu (TW)

(21) Appl. No.: 18/999,478

(22) Filed: Dec. 23, 2024

Related U.S. Application Data
(60) Provisional application No. 63/684,764, filed on Aug. 19, 2024.

(51) Int. Cl. G11C 7/10; G11C 7/22

(52) U.S. Cl. CPC G11C 7/1093; G11C 7/1096; G11C 7/222

(57) ABSTRACT

A circuit includes a first number of computing cells, wherein each of the computing cells comprises a second number of stages which, when collectively performed, are configured to provide at least one MAC result of a respective plurality of input data elements and a respective plurality of weight data elements. The circuit includes a global CIM controller operatively coupled to the computing cells, and is configured to schedule a first one of the stages of a first one of the computing cells and a first one of the stages of a second one of the computing cells to be simultaneously performed, based on identifying that a first peak current previously consumed by the first stage of the first computing cell and a second peak current previously consumed by the first stage of the second computing cell are different.

### CROSS-REFERENCE TO RELATED APPLICATION

This application claims priority to and the benefit of U.S. Provisional Application No. 63/684,764, filed Aug. 19, 2024, entitled “CIM Ipeak Suppression,” which is incorporated herein by reference in its entirety for all purposes.

### BACKGROUND

Computer artificial intelligence (AI) has been built on machine learning, for example, using deep learning techniques. With machine learning, a computing system organized as a neural network computes a statistical likelihood of a match of input data with prior computed data. A neural network refers to a number of interconnected processing nodes that enable the analysis of data to compare an input to “trained” data. Trained data refers to computational analysis of properties of known data to develop models to use to compare input data. An example of an application of AI and data training is found in object recognition, where a system analyzes the properties of many (e.g., thousands or more) of images to determine patterns that can be used to perform statistical analysis to identify an input object.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of a CIM circuit with multiple computing cells, each of the computing cells including multiple MAC stages, in accordance with some embodiments.

FIG. 2 illustrates a block diagram of one of the computing cells of the CIM circuit of FIG. 1, in accordance with some embodiments.

FIG. 3 illustrates a block diagram of one of the computing cells of the CIM circuit of FIG. 1, in accordance with some embodiments.

FIG. 4 illustrates a block diagram of one of the computing cells of the CIM circuit of FIG. 1, in accordance with some embodiments.

FIG. 5 is a schematic diagram illustrating how the CIM circuit of FIG. 1 schedules the MAC stags across the computing cells, in accordance with some embodiments.

FIG. 6 illustrates waveforms of signals when one of the computing cells of the CIM circuit of FIG. 1 schedules a MAC stage and a write operation, in accordance with some embodiments.

FIG. 7 illustrates an example flow chart of a method for operating the CIM circuit of FIG. 1, in accordance with some embodiments.

FIG. 8 illustrates an example flow chart of a method for operating the CIM circuit of FIG. 1, in accordance with some embodiments.

FIG. 9 illustrates an example flow chart of a method for operating the CIM circuit of FIG. 1, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus maybe otherwise oriented (rotated 90 degrees or at other orientations) and the spatially relative descriptors used herein may likewise be interpreted accordingly.

In general, neural networks compute “weights” to perform computation on new data (an input data “word”). Neural networks use multiple layers of computational nodes, where deeper layers perform computations based on results of computations performed by higher layers. Machine learning currently relies on the computation of dot-products and absolute difference of vectors, typically computed with multiply-accumulate (MAC) operations performed on the parameters, input data and weights. The computation of large and deep neural networks typically involves so many data elements, and thus it is not practical to store them in processor cache. Accordingly, these data elements are usually stored in a memory.

Machine learning can be very computationally intensive with the computation and comparison of many different data elements. The computation of operations within a processor is orders of magnitude faster than the transfer of data elements between the processor and main memory resources. Placing all the data elements closer to the processor in caches is prohibitively expensive for the great majority of practical systems due to the memory sizes needed to store the data elements. Thus, the transfer of data elements becomes a major bottleneck for AI computations. As the data sets increase, the time and power/energy a computing system uses for moving data elements around can end up being multiples of the time and power used to actually perform computations.

In this regard, compute-in-memory (CIM) circuits or systems have been proposed to perform such MAC operations. Generally, a CIM circuit instead conducts data processing in situ within a suitable memory circuit. The CIM circuit suppresses the latency for data/program fetch and output results upload in corresponding memory (e.g. a memory array), thus solving the memory (or von Neumann) bottleneck of conventional computers. Another key advantage of the CIM circuit is the high computing parallelism, thanks to the specific architecture of the memory array, where computation can take place along several current paths at the same time. The CIM circuit also benefits from the high density of multiple memory arrays with computational devices, which generally feature excellent scalability and the capability of three-dimensional (3D) integration. As a non-limiting example, the CIM circuit targeted for various machine learning applications can perform the MAC operations locally within the memory (i.e., without having to send data elements to a host processor) to enable higher throughput dot-product of neuron activation and weight matrices, while still providing higher performance and lower energy compared to computation by the host processor.

The data elements, processed by the CIM circuit, have various data types or forms, such as an integer data type and a floating point data type. The integer data types, each of which represents a range of mathematical integers, may be of different sizes. For example, the integer data types are of 4 bits (sometimes referred to as an INT4 data type), 8 bits (sometimes referred to as an INT8 data type), etc. The floating point data type is typically represented by a sign portion, an exponent portion, and a significand (mantissa) portion that consists of the significant digits of the number. For example, one floating point number format specified by the Institute of Electrical and Electronics Engineers (IEE®) has sixteen bits in size (sometimes referred to as an FP16 data type), which includes ten mantissa bits, five exponent bits, and one sign bit. Another floating point number format also has sixteen bits in size (sometimes referred to as a BF16 data type), which includes seven mantissa bits, eight exponent bits, and one sign bit.

In machine learning applications, the CIM circuit is frequently configured to process dot products based on performing MAC operations on a large number of data elements (e.g., an input word vector and a weight matrix), which may each be in the integer data type or the floating point data type, and then process addition (or accumulation) of the dot products to provide one or more MAC results. To process a large amount of data elements, it has been proposed to include multiple computing cells in a CIM circuit. Such computing cells (which are sometimes referred to as CIM macros) can each have multiple MAC stages, each of which is configured to perform a certain MAC-related or CIM-related operation, allowing the CIM macro to provide a corresponding MAC result. For example, each of the MAC stages can be configured to perform one or more multiplication operations, one or more accumulation operations, one or more subtraction operations, or one or more alignment operations.

However, in the existing technologies, no arrangement on the MAC stages across different CIM macros, in terms of taking into account peak currents of the different MAC stages, has been considered. For example, the existing CIM circuit typically have two or more of its CIM macros to perform the same MAC stages that are associated with the same or similarly high peak current at the same time. In this way, the existing CIM circuit consumes a significantly high amount of an overall peak current, which disadvantageously impacts performance of the CIM circuit. This abnormally high peak current typically causes a supply voltage of the CIM circuit to change, e.g., VDD drop and/or VSS bump. Thus, the existing CIM circuits have not been entirely satisfactory in certain aspects.

The present disclosure provides various embodiments of a compute-in-memory (CIM) circuit that can arrange the MAC stages of different computing cells (CIM macros) that are associated with the same peak current to be performed at different timings (e.g., different clock cycles). As such, the amount of an overall peak current consumed by the different computing cells can be significantly suppressed. For example, the CIM circuit, as disclosed herein, can include multiple (e.g., M) computing cells, each of which can include multiple (e.g., N) MAC stages, and a global CIM controller. The MAC stages can be operatively coupled to one another, which can be sequentially performed to form a pipeline. In various embodiments, each MAC stage can include one or more MAC-related or otherwise CIM-related operations, for example, one or more multiplication operations, one or more accumulation operations, one or more subtraction operations, and one or more alignment operations. The global CIM controller, operatively coupled to the M computing cells, can identify respective peak currents (or peak current levels) associated with the NMAC stages (e.g., I₁, I₂, I₃ . . . I_{N}). Based on the current levels, the global CIM controller can arrange or otherwise schedule the MAC stages of different computing cells that are associated with the same peak current to be performed at different timings. Alternatively stated, the global CIM controller can arrange or otherwise schedule the MAC stages of different computing cells that are associated with different peak current to be performed at the same timing. As such, the amount of overall peak current consumed by the disclosed CIM circuit can be largely reduced. For example, the disclosed CIM circuit can present its overall peak current to have a maximum value as a sum of the respective peak currents of the different MAC stages (e.g., I₁+I₂+I₃ . . . I_{N}), instead of a product of M times a maximum among the peak currents (e.g., M×I_{N}) like the existing CIM circuit that typically perform the MAC stages of different computing cells with the same peak current at the same timing.

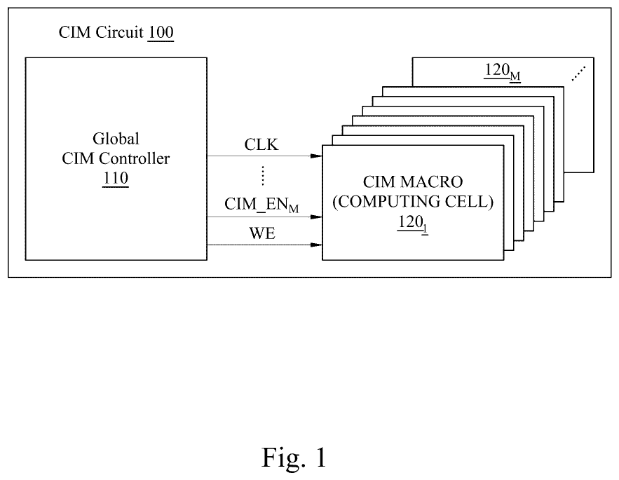

FIG. 1 illustrates a block diagram of a CIM circuit 100, in accordance with some embodiments. The CIM circuit 100 may include or be an implementation of a CIM accelerator (or processor) that can help address memory access issues for deep neural networks. In the illustrated embodiment of FIG. 1, the CIM circuit 100 includes various components collectively configured to perform in-memory computations (e.g., multiply-accumulate (MAC) operations) on a number of first data elements (e.g., input word vectors) and a number of second data elements (e.g., weight matrices).

In various embodiments, each of the input word vectors can include a plural number of input data elements InDE, and each of the weight matrices can include a plural number of weight data elements WtDE. In one aspect of the present disclosure, each of the input data elements InDE and the weight data elements WtDE may include an integer number. In another aspect of the present disclosure, each of the input data elements InDE and the weight data elements WtDE may include a floating point number.

As shown, the CIM circuit 100 includes a global CIM controller 110 and a plural number (AI) of computing cells 120. For example, the CIM circuit 100 can include computing cells 120, e.g., 120₁, 120₂ . . . 120_{M}. As a brief overview, each of the computing cells 120 is configured to provide one or more multiply-accumulate (MAC) results, e.g., a partial sum of a number of input data elements InDE and a number of weight data elements WtDE. The global CIM controller 110 is configured to identify respective peak currents of plural MAC stages of each computing cell 120, and thus schedule the MAC stages across different computing cells 120 that have different peak currents to be performed at the same timing, so as to avoid accumulating all the same high peak currents (from different computing cells) at the same timing, which will be discussed as follows.

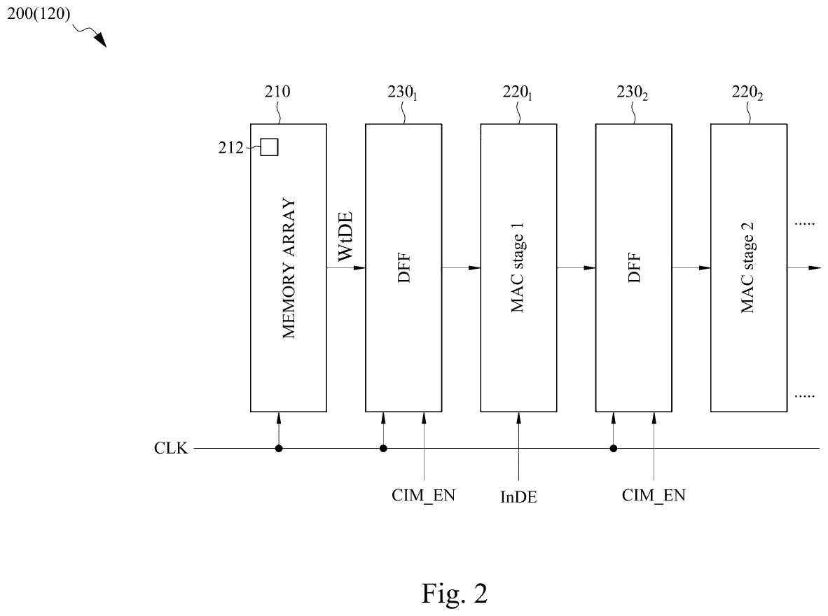

In one embodiment, each of the computing cells 120 can include a memory array and a plural number (N) of MAC stages. The memory array and the multiple MAC stages can be operatively coupled to one another as a pipeline, and the MAC stages, when sequentially performed, can each be configured to perform one or more multiplication operations, one or more accumulation operations, one or more subtraction operations, or one or more alignment operations. The computing cells 120₁ to 120_{M} can receive a clock (CLK) signal from the global CIM controller 110. The computing cells 120₁ to 120_{M} can receive respective CIM enable (CIM_EN) signals from the global CIM controller 110. The global CIM controller 110 can utilize these CIM_EN signals to schedule the MAC stages of different computing cells 120 that share a similar peak current to be performed at different timings (e.g., different clock cycles), thereby avoiding accumulating the same high peak current at the same timing (e.g., the same clock cycle). Such an embodiment of the computing cell 120 will be discussed further in FIG. 2.

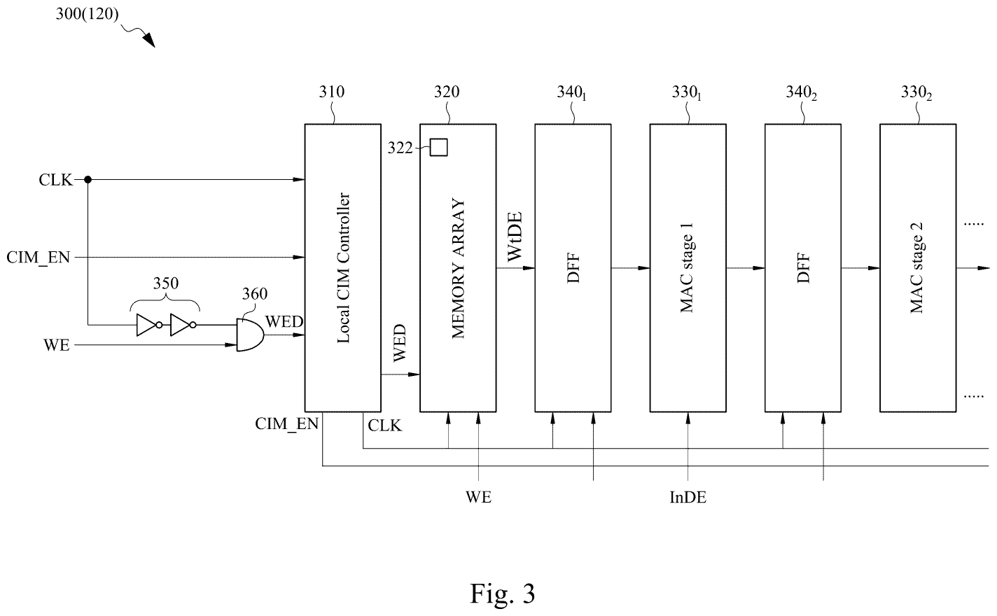

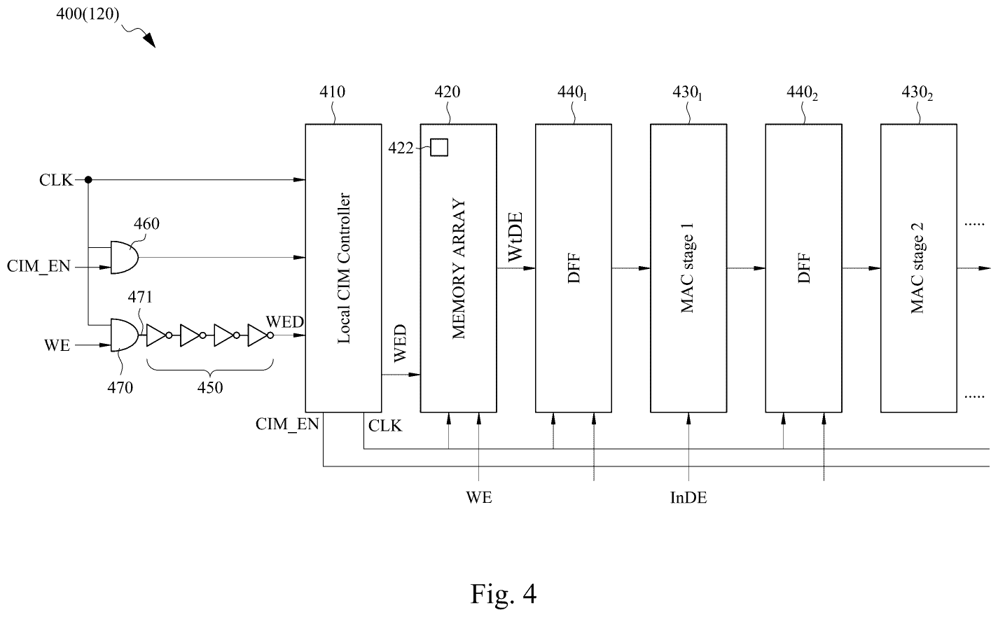

In another embodiment, each of the computing cells 120 can include a local CIM controller, a memory array, and a plural number (N) of MAC stages. The local CIM controller, the memory array, and the multiple MAC stages can be operatively coupled to one another as a pipeline, and the MAC stages, when sequentially performed, can each be configured to perform one or more multiplication operations, one or more accumulation operations, one or more subtraction operations, or one or more alignment operations. The computing cells 120₁ to 120_{M} can receive a clock (CLK) signal from the global CIM controller 110. The computing cells 120₁ to 120_{M} can receive respective CIM enable (CIM_EN) signals from the global CIM controller 110. In some embodiments, the computing cells 120₁ to 120_{M} can each further receive a write enable (WE) signal from the global CIM controller 110. The global CIM controller 110 can utilize these CIM_EN signals to schedule the MAC stages of different computing cells 120 that share a similar peak current to be performed at different timings (e.g., different clock cycles). In addition, the global CIM controller 110 can utilize the WE signal to enable each of the computing cells 120 to perform a write operation that allows data elements to be written to its corresponding memory array. The received WE signal can be delayed by each of the computing cells 120, which allows the computing cell 120 to select to shift a write operation with respect to a MAC stage. According to the delayed WE (WED) signal, the computing cell 120 can selectively perform a write operation and a MAC stage at the same timing, perform only a write operation, or perform only a MAC stage. As such, even simultaneously performing a write operation and a MAC stage, accumulation of peak currents can be optimized. Such an embodiment of the computing cell 120 will be discussed further in FIG. 3 and FIG. 4.

The memory array of each of the computing cells 120 includes a storage device with a plural number of storage elements (sometimes referred to as memory cells or memory bits). Each of the storage elements includes an electrical, electromechanical, electromagnetic, or other device configured to store one or more data elements, each data element including one or more data bits represented by logical states. In some embodiments, a logical state corresponds to a voltage level of an electrical charge stored in a portion or all of a storage element. In some embodiments, a logical state corresponds to a physical property, e.g., a resistance or magnetic orientation, of a portion or all of a storage element.

In some embodiments, the storage element may include one or more static random-access memory (SRAM) cells. In various embodiments, an SRAM cell includes a number of transistors, e.g., a five-transistor (5T) SRAM cell, a six-transistor (6T) SRAM cell, an eight-transistor (8T) SRAM cell, a nine-transistor (9T) SRAM cell, etc. In some embodiments, the storage element may include one or more dynamic random-access memory (DRAM) cells, resistive random-access memory (RRAM) cells, magnetoresistive random-access memory (MRAM) cells, ferroelectric random-access memory (FeRAM) cells, NOR flash cells, NAND flash cells, conductive-bridging random-access memory (CBRAM) cells, data registers, non-volatile memory (NVM) cells, 3D NVM cells, or other memory cell types capable of storing bit data.

In addition to the memory array, each of the computing cells 120 can include a number of circuits to access or otherwise control the memory array. Such circuits can be integrated into or coupled to the memory array. For example, the computing cell 120 may include a (e.g., word line) driver operatively coupled to the memory array. The word line driver can apply signals (e.g., voltages) to the corresponding storage elements so as to allow those storage element to be accessed (e.g., programmed, read, etc.). For another example, the computing cell 120 may include a programming circuit and/or a read circuit that are integrated into or operatively coupled to the memory array.

FIG. 2 illustrates a block diagram of one example implementation of the computing cell 120 (hereinafter “computing cell 200”), in accordance with some embodiments. In general, the computing cell 200 is configured to perform a series of MAC-related operations on a number of input data elements InDE and a number of weight data elements WtDE to generate one or more MAC results (e.g., partial sums) of those data elements InDE and WtDE. It should be appreciated that the block diagram depicted in FIG. 2 has been simplified, and thus, the computing cell 200 can include any of various other components while remaining within the scope of the present disclosure.

As shown in FIG. 2, the computing cell 200 includes a memory array 210 and a plural number (N) of MAC stages, e.g., 220₁, 220₂, etc. Although two MAC stages, 220₁ and 220₂, are shown, it should be appreciated that Nis not necessarily equal to 2 and can be any integer number equal to or greater than 2 while remaining within the scope of the present disclosure. Coupled to each MAC stage, the computing cell 200 can further include a respective latch device such as, for example, a D-type flip flop (DFF). In the example of FIG. 2, a first DFF 230₁ is coupled to the first MAC stage220₁, a second DFF 230₂ is coupled to the second MAC stage 220₂, and so on. In some embodiments, the first DFF 230₁, the first MAC stage220₁, the second DFF 230₂, the second MAC stage 220₂, and the following DFF(s) and MAC stage(s), which are not shown for brevity, can form a pipeline. Under such a pipeline configuration, the memory array 210 and the DFFs 230 can receive the CLK signal from the global CIM controller 110 (FIG. 1), with the DFFs 230 each further receiving the CIM_EN signal from the global CIM controller 110 (FIG. 1). Each of the MAC stages can be configured to perform a MAC-related operation based on the MAC-related operation performed by a previous MAC stage, causing this pipeline to generate one or more MAC results.

In some embodiments, the memory array 210 includes a plural number of storage elements 212 configured to store the weight data elements WtDE, which can be provided to the first DFF 230₁. The first DFF 230₁ can latch the weight data elements WtDE. Upon being activated by the CIM_EN signal, the first DFF 230₁ can provide the latched weight data elements WtDE to the first MAC stage220₁. The first MAC stage220₁ can be configured to further receive the input data elements InDE, and perform a corresponding MAC-related operation on the received data elements. The CIM_EN signal can concurrently activate the second DFF 230₂, which causes the second DFF 230₂ to provide data elements (e.g., intermediate or partial MAC results) to the second MAC stage 220₂. The second MAC stage 220₂ can be configured to perform a corresponding MAC-related operation on the received data elements. In some other embodiments, the storage elements 212 of the memory array 210 can instead store the input data elements InDE, with first MAC stage220₁ configured to receive the weight data elements WtDE.

As a non-limiting example where the weight data elements WtDE and input data elements InDE are with an integer data type, the first MAC stage220₁ may include multiple multipliers. The first MAC stage220₁ may be configured to perform multiplication operations on the weight data elements WtDE and the input data elements InDE to provide multiple partial MAC results. For instance, each of these partial MAC results can be a product of a corresponding one of the input data elements InDE (e.g., InDE₀) and a corresponding one of the weight data elements WtDE (e.g., WtDE₀), i.e., InDE₀×WtDE₀. The second MAC stage 220₂ may include multiple adders, which can form an adder tree. The second MAC stage 220₂ may be configured to perform accumulation operations on those partial MAC results. For instance, the second MAC stage 2202 can sum up all the partial MAC results, e.g., InDE₀×WtDE₀+InDE₁×WtDE₁+InDE₂×WtDE₂ . . . , to provide a MAC result.

As another non-limiting example where the weight data elements WtDE and input data elements InDE are with a floating point data type, each of the weight data elements WtDE and input data elements InDE may include at a mantissa portion, WtDE_{M}, InDE_{M}, and an exponent portion, WtDE_{E}, InDE_{E}. The first MAC stage220₁, which may include multiple multipliers, is configured to perform multiplication operations on respective mantissa portions of the weight data elements WtDE and the input data elements InDE to provide multiple first partial MAC results. For instance, each of these first partial MAC results can be a mantissa product of a corresponding one of the input data elements InDE (e.g., InDE_{M0}) and a corresponding one of the weight data elements WtDE (e.g., WtDE_{M0}), i.e., InDE_{M0}λWtDE_{M0}. The second MAC stage 220₂, which may include multiple adders, is configured to perform accumulation operations on respective exponent portions of the weight data elements WtDE and the input data elements InDE to provide multiple second partial MAC results. For instance, each of these second partial MAC results can be an exponent sum of a corresponding one of the input data elements InDE (e.g., InDE_{E0}) and a corresponding one of the weight data elements WtDE (e.g., WtDE_{E0}), i.e., InDE_{E0}+WtDE_{E0}. Following the second MAC stage 220₂, another MAC stage (not shown) can be configured to shift the mantissa products (e.g., the first partial MAC results) by aligning their respective exponent sums (e.g., the second partial MAC results) with a maximum one among all the exponent sums. Such an operation is sometimes referred to as an alignment operation or shifting operation.

FIG. 3 illustrates a block diagram of another example implementation of the computing cell 120 (hereinafter “computing cell 300”), in accordance with some embodiments. In general, the computing cell 300 is configured to perform a series of MAC-related operations on a number of input data elements InDE and a number of weight data elements WtDE to generate one or more MAC results (e.g., partial sums) of those data elements InDE and WtDE. It should be appreciated that the block diagram depicted in FIG. 3 has been simplified, and thus, the computing cell 300 can include any of various other components while remaining within the scope of the present disclosure.

As shown in FIG. 3, the computing cell 300 includes a local CIM controller 310, a memory array 320, and a plural number (N) of MAC stages, e.g., 330₁, 330₂, etc. Although two MAC stages, 330₁ and 330₂, are shown, it should be appreciated that Nis not necessarily equal to 2 and can be any integer number equal to or greater than 2 while remaining within the scope of the present disclosure. Coupled to each MAC stage, the computing cell 300 can further include a respective latch device such as, for example, a D-type flip flop (DFF). In the example of FIG. 3, a first DFF 340₁ is coupled to the first MAC stage330₁, a second DFF 340₂ is coupled to the second MAC stage 330₂, and so on. In some embodiments, the first DFF 340₁, the first MAC stage 3301, the second DFF 340₂, the second MAC stage 330₂, and the following DFF(s) and MAC stage(s), which are not shown for brevity, can form a pipeline. Under such a pipeline configuration, the memory array 320 and the DFFs 340 can receive the CLK signal from the global CIM controller 110 (FIG. 1) through the local CIM controller 310, with the DFFs 340 each further receiving the CIM_EN signal from the global CIM controller 110 (FIG. 1) through the local CIM controller 310. Each of the MAC stages 330 can be configured to perform a MAC-related operation based on the MAC-related operation performed by a previous MAC stage, causing this pipeline to generate one or more MAC results.

In some embodiments, the memory array 320 includes a plural number of storage elements 322 configured to store the weight data elements WtDE, which can be provided to the first DFF 340₁. The first DFF 340₁ can latch the weight data elements WtDE. Upon being activated by the CIM_EN signal, the first DFF 340₁ can provide the latched weight data elements WtDE to the first MAC stage 3301. The first MAC stage 3301 can be configured to further receive the input data elements InDE, and perform a corresponding MAC-related operation on the received data elements. The CIM_EN signal can concurrently activate the second DFF 340₂, which causes the second DFF 340₂ to provide data elements (e.g., intermediate or partial MAC results) to the second MAC stage 330₂. The second MAC stage 330₂ can be configured to perform a corresponding MAC-related operation on the received data elements. In some other embodiments, the storage elements 322 of the memory array 320 can instead store the input data elements InDE, with first MAC stage 3301 configured to receive the weight data elements WtDE. As discussed above with respect to FIG. 2, each of the MAC stages 330 can be configured to perform a MAC-related operation (e.g., one or more multiplication operations, one or more accumulation operations, one or more alignment operations) based on a data type of the input data elements InDE and the weight data elements WtDE. Accordingly, the discussion will not be repeated.

In some embodiments, the computing cell 300 can further include an even number of inverters 350 and a logic gate (e.g., an AND gate) 360 coupled between the global CIM controller 110 (FIG. 1) and the local CIM controller 310. The local CIM controller 310 is configured to receive an altered version of the WE signal (WED signal) delayed through the inverters 350 and logic gate 360. The memory array 320 can receive the WED signal, and based on the WED signal (e.g., with an amount of delay), the computing cell 300 can shift a write operation configured to write (e.g., weight) data elements into the storage elements 322 of the memory array 320. As such, when simultaneously performing one of the MAC stages (e.g., associated with a relatively high peak current) and the write operation, shifting the write operation with a delay can avoid the overall peak current from being accumulated too quickly. For example, the CLK signal received from the global CIM controller 110 is delayed through the inverters 350 (which may form a delay chain) and provided to a first input of the logic gate 360. The WE signal received from the global CIM controller 110 is provided to a second input of the logic gate 360. Upon receiving the delayed CLK signal and the WE signal, the logic gate 360 can provide the WED signal to the local CIM controller 310.

FIG. 4 illustrates a block diagram of yet another example implementation of the computing cell 120 (hereinafter “computing cell 400”), in accordance with some embodiments. In general, the computing cell 400 is configured to perform a series of MAC-related operations on a number of input data elements InDE and a number of weight data elements WtDE to generate one or more partial sums of those data elements InDE and WtDE. It should be appreciated that the block diagram depicted in FIG. 4 has been simplified, and thus, the computing cell 400 can include any of various other components while remaining within the scope of the present disclosure.

As shown in FIG. 4, the computing cell 400 includes a local CIM controller 410, a memory array 420, and a plural number (N) of MAC stages, e.g., 430₁, 430₂, etc. Although two MAC stages, 430₁ and 430₂, are shown, it should be appreciated that Nis not necessarily equal to 2 and can be any integer number equal to or greater than 2 while remaining within the scope of the present disclosure. Coupled to each MAC stage, the computing cell 400 can further include a respective latch device such as, for example, a D-type flip flop (DFF). In the example of FIG. 4, a first DFF 440₁ is coupled to the first MAC stage 430₁, a second DFF 440₂ is coupled to the second MAC stage 430₂, and so on. In some embodiments, the first DFF 440₁, the first MAC stage 430₁, the second DFF 440₂, the second MAC stage 430₂, and the following DFF(s) and MAC stage(s), which are not shown for brevity, can form a pipeline. Under such a pipeline configuration, the memory array 420 and the DFFs 440 can receive the CLK signal from the global CIM controller 110 (FIG. 1) through the local CIM controller 410, with the DFFs 440 each further receiving the CIM_EN signal from the global CIM controller 110 (FIG. 1) through the local CIM controller 410. Each of the MAC stages 430 can be configured to perform a MAC-related operation based on the MAC-related operation performed by a previous MAC stage, causing this pipeline to generate one or more MAC results.

In some embodiments, the memory array 420 includes a plural number of storage elements 422 configured to store the weight data elements WtDE, which can be provided to the first DFF 440₁. The first DFF 440₁ can latch the weight data elements WtDE. Upon being activated by the CIM_EN signal, the first DFF 440₁ can provide the latched weight data elements WtDE to the first MAC stage 430₁. The first MAC stage 430₁ can be configured to further receive the input data elements InDE, and perform a corresponding MAC-related operation on the received data elements. The CIM_EN signal can concurrently activate the second DFF 440₂, which causes the second DFF 440₂ to provide data elements (e.g., intermediate or partial MAC results) to the second MAC stage 430₂. The second MAC stage 430₂ can be configured to perform a corresponding MAC-related operation on the received data elements. In some other embodiments, the storage elements 422 of the memory array 420 can instead store the input data elements InDE, with first MAC stage 430₁ configured to receive the weight data elements WtDE. As discussed above with respect to FIG. 2, each of the MAC stages 430 can be configured to perform a MAC-related operation (e.g., one or more multiplication operations, one or more accumulation operations, one or more alignment operations) based on a data type of the input data elements InDE and the weight data elements WtDE. Accordingly, the discussion will not be repeated.

In some embodiments, the computing cell 400 can further include an even number of inverters 450 and a number of logic gates (e.g., AND gates) 460 and 470 coupled between the global CIM controller 110 (FIG. 1) and the local CIM controller 410. The local CIM controller 410 is configured to receive an altered version of the WE signal (WED signal) delayed through the inverters 450 and logic gates 460-470. The memory array 420 can receive the WED signal, and based on the WED signal (e.g., an amount of delay), the computing cell 400 can shift a write operation configured to write (e.g., weight) data elements into the storage elements 422 of the memory array 420. As such, when simultaneously performing one of the MAC stages (e.g., associated with a relatively high peak current) and the write operation, shifting the write operation with a delay can avoid the overall peak current from being accumulated too quickly. For example, the CLK signal received from the global CIM controller 110 is provided to a first input of the logic gate 460 and a first input of the logic gate 470, with a second input of the logic gate 460 and a second input of the logic gate 470 configured to receive the CIM_EN signal and WE signal (from the global CIM controller 110), respectively. The logic gate 470 can AND the CLK signal and the WE signal, and provide an output signal 471 to the inverters 450 (which form a delay chain). The output signal 471 is delayed through the inverters 450 as the WED signal.

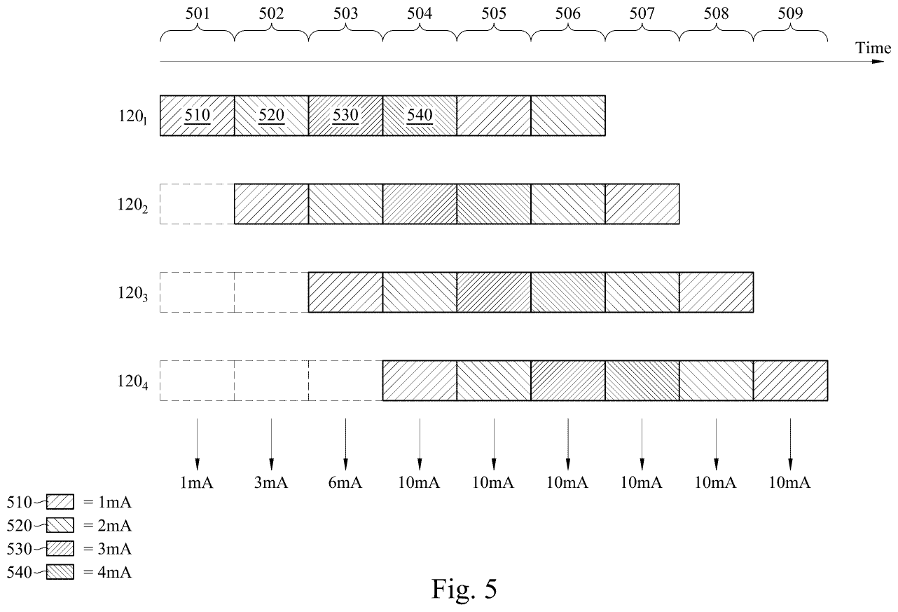

FIG. 5 is an example schematic diagram illustrating how the CIM circuit 100 (FIG. 1) schedules the MAC stages of different computing cells 120, in accordance with some embodiments. Although 4 computing cells (e.g., 120₁, 120₂, 120₃, 120₄), each configured with 4 MAC stages (e.g., 510, 520, 530, 540), are shown (i.e., M=4 & N=4), it should be appreciated that M and N can each be any integer number while remaining within the scope of the present disclosure. In some embodiments, each of the computing cells 120₁ to 120₄ shown in FIG. 5 may be implemented as the computing cell 200 of FIG. 2, in which any of the MAC stages 510 to 540 can be performed in parallel with a write operation.

Prior to performing any MAC stage, the global CIM controller 110 can identify respective peak currents consumed by the MAC stages. The term “peak current,” as used herein, can refer to a highest monitored current of a computing cell when performing a MAC stage. In some embodiments, the global CIM controller 110 can identify the peak currents from previously performed MAC-related operations, store the peak currents therein, and associate the peak currents with respective MAC stages (or with respective MAC-related operations). In the illustrated example of FIG. 5, the global CIM controller 110 can identify the peak currents associated with the MAC stages 510, 520, 530, and 540, as about 1 mA, 2 mA, 3 mA, and 4 mA, respectively. The computing cell 120₁ can perform a pipeline consisting of one or more iterations of the MAC stages 510, 520, 530, and 540; the computing cell 120₂ can perform a pipeline consisting of one or more iterations of the MAC stages 510, 520, 530, and 540; the computing cell 120₃ can perform a pipeline consisting of one or more iterations of the MAC stages 510, 520, 530, and 540; and the computing cell 120₄ can perform a pipeline consisting of one or more iterations of the MAC stages 510, 520, 530, and 540.

Further, the computing cells 120 can each perform one of its MAC stages 510 to 540 according to a clock cycle, in some embodiments. Such a clock cycle may have the same frequency as the CLK signal shown in FIG. 2. For example in FIG. 5, during each of clock cycles 501, 502, 503, 504, 505, 506, 507, 508, and 509, each of the computing cells 120₁ to 1204 can perform one the MAC stages 510, 520, 530, or 540. During the clock cycle 501, the computing cell 120₁ may perform the MAC stage 510; during the clock cycle 502, the computing cells 120₁ and 120₂ may perform the MAC stages 520 and 510, respectively; during the clock cycle 503, the computing cells 120₁, 120₂, and 120₃ may perform the MAC stages 530, 520, and 510, respectively; during the clock cycle 504, the computing cells 120₁, 120₂, 120₃, and 120₄ may perform the MAC stages 540, 530, 520, and 510, respectively; and so on.

In the existing CIM circuits, the computing cells 120₁ to 120₄ simultaneously perform the same MAC stage at the same timing, or during the same clock cycle. Stated another way, the computing cells 120₁ to 120₄ perform the same MAC stage in parallel. This disadvantageously accumulates the peak current to an undesired high level. For example, when the computing cells 120₁ to 120₄ simultaneously perform the MAC stage 540 that is associated with the highest peak current (e.g., 4 mA), the overall peak current consumed by the CIM circuit (4 computing cells) is accumulated to at least 16 mA (4×4). By contrast, the global CIM controller 110, as disclosed herein, can schedule (e.g., shift) the MAC stages performed by different computing cells 120 based on their associated peak currents. The MAC stages, performed by different computing cells 120₁ to 120₄ of the disclosed CIM circuit 100, may be staggered. Accordingly, the total peak current accumulated or consumed by the disclosed CIM circuit 100 at any timing can be significantly reduced.

For example, to avoid other computing cells 120₂ to 120₄ from consuming the same level of high peak current when the computing cell 120₁ is performing the MAC stage 540 (associated with the highest peak current), the global CIM controller 110 can shift the MAC stage 510 performed by the computing cell 120₂ to align with the MAC stage 520 performed by the computing cell 120₁. Similarly, the global CIM controller 110 can shift the MAC stage 510 performed by the computing cell 120₃ to align with the MAC stage 530 performed by the computing cell 120₁, which accordingly aligns with the MAC stage 520 performed by the computing cell 120₂; and the global CIM controller 110 can shift the MAC stage 510 performed by the computing cell 120₄ to align with the MAC stage 540 performed by the computing cell 120₁, which accordingly aligns with the MAC stage 530 performed by the computing cell 120₂ and the MAC stage 520 performed by the computing cell 120₃. Consequently, the total peak current, consumed by at least one of the computing cells 120₁, 120₂, 120₃, or 120₄, can have a maximum equal to or less than 10mA. This maximum total peak current is a sum of the respectively “different” peak currents of the MAC stages 510 to 540 (e.g., 1 mA+2 mA+3 mA+4 mA), instead of a product of N (e.g., 4 in the current example) times the highest peak current (e.g., 4 mA). By scheduling the MAC stages based on their associated peak currents, it advantageously helps the disclosed CIM circuit avoid from accumulating the same high peak current at the same timing.

In general, once the global CIM controller 110 of the CIM circuit 100 identifies that one MAC stage performed by a first computing cell 120 is associated with the highest peak current, the global CIM controller 110 can shift or schedule the MAC stages of other computing cells 120 to avoid their MAC stages with the same highest peak current from colliding with the MAC stage of that first computing cell 120. Stated another way, the MAC stages with the highest peak current, performed by different computing cells, respectively, are not aligned with each other in a time domain. Accordingly, the total peak current consumed by the disclosed CIM circuit 100 can be significantly suppressed.

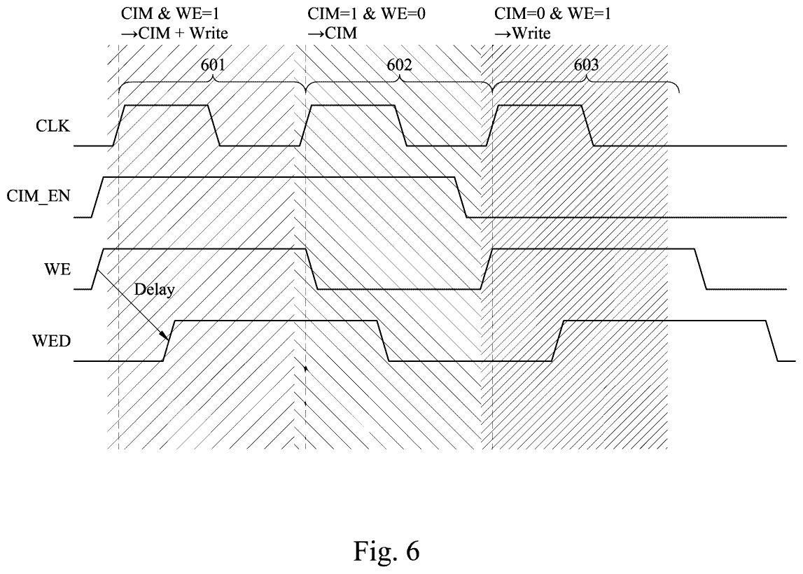

FIG. 6 illustrates example waveforms of various signals when one of the computing cells 120 of the CIM circuit 100 (FIG. 1) schedules one or more of the MAC stages with respect to a write operation, in accordance with some embodiments. It should be noted that the CIM circuit can include multiple computing cells 120 to perform similar staggered MAC stages, as discussed in FIG. 5, and thus, the discussion on such staggered MAC stages across different computing cells will not be repeated. The computing cell 120 discussed with respect to FIG. 6 may be implemented as the computing cell 300 of FIG. 3 or the computing cell 400 of FIG. 4, in which a write operation can be selectively performed in parallel with any of the MAC stages.

As shown, over three clock cycles 601, 602, and 603 of the CLK signal, different operation combinations can be performed. For example, during the clock cycle 601, the CIM_EN signal and the WE signal are both asserted (e.g., pulled high), causing the computing cell 120 to perform one MAC stage and a write operation; during the clock cycle 602, the CIM_EN signal is asserted (e.g., pulled high) and the WE signal is deasserted (e.g., pulled low), causing the computing cell 120 to perform another MAC stage only; and during the clock cycle 603, the CIM_EN signal is deasserted (e.g., pulled low) and the WE signal is asserted (e.g., pulled high), causing the computing cell 120 to perform another write operation only. Further, during the clock cycle 601, the computing cell 120, through the local CIM controller 310 of FIG. 3 or 410 of FIG. 4, can delay the WE signal as the WED signal to shift the write operation with respect to the MAC stage. This can advantageously alleviate (e.g., reduce) accumulation of the peak current during the clock cycle 601.

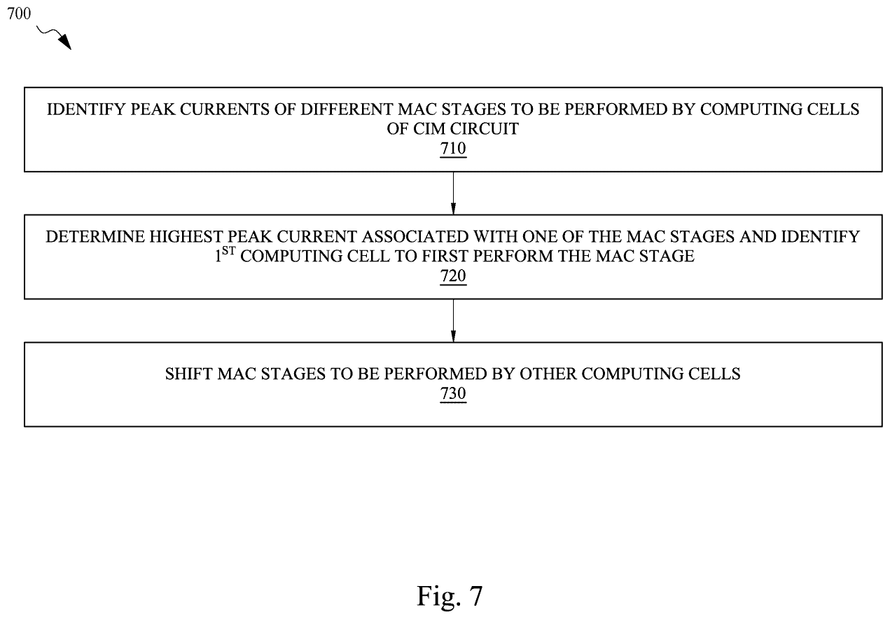

FIG. 7 illustrates a flow chart of a method 700 for scheduling MAC stages of different computing cells independent from write operations, in accordance with some embodiments. The example method 700 can be performed by the CIM circuit 100 with its multiple computing cells each implemented as the computing cell 200 of FIG. 2. As such, the following embodiment of the method 700 can be described in conjunction with but not limited to at least one of FIG. 1 or 2. The illustrated embodiment of the method 700 is provided as an example and does not intent to limit the scope of the present disclosure. Therefore, it shall be understood that any of a variety of the operations of the method 700 may be omitted, re-sequenced, and/or added while remaining within the scope of the present disclosure.

The method 700 starts with operation 710 of identifying respective peak currents of different MAC stages to be performed by a plural number of computing cells of a CIM circuit. For example, the global CIM controller 110 of the CIM circuit 100 (FIG. 1) can identify the peak currents of different MAC stages 510 to 540 (FIG. 5), to be performed by each of the computing cells 120₁ to 120_{M}, as 1 mA, 2 mA, 3 mA, and 4 mA, respectively. Next, the method 700 continues to operation 720 of determining a highest peak current associated with one of the MAC stages and identifying that a first computing cell is configured to first perform this MAC stage. Continuing with the above example, the global CIM controller 110 can determine the MAC stage, associated with the highest peak current, as the MAC stage 540, and identify that the MAC stage 540 is to be first performed by the computing cell 120₁ during the clock cycle 504. Following operation 720, the method 700 continues to operation 730 of shifting MAC stages to be performed by other computing cells based on the MAC stage with the highest peak current performed by the first computing cell. Still with the same example, the global CIM controller 110 can shift (e.g., schedule) all the MAC stages to be performed by the computing cells 120₂, 120₃, and 120₄, respectively. Specifically, the MAC stages performed by the computing cells 120₂ may be shifted to start from the clock cycle 502; the MAC stages performed by the computing cells 120₃ may be shifted to start from the clock cycle 503; and the MAC stages performed by the computing cells 120₄ may be shifted to start from the clock cycle 504.

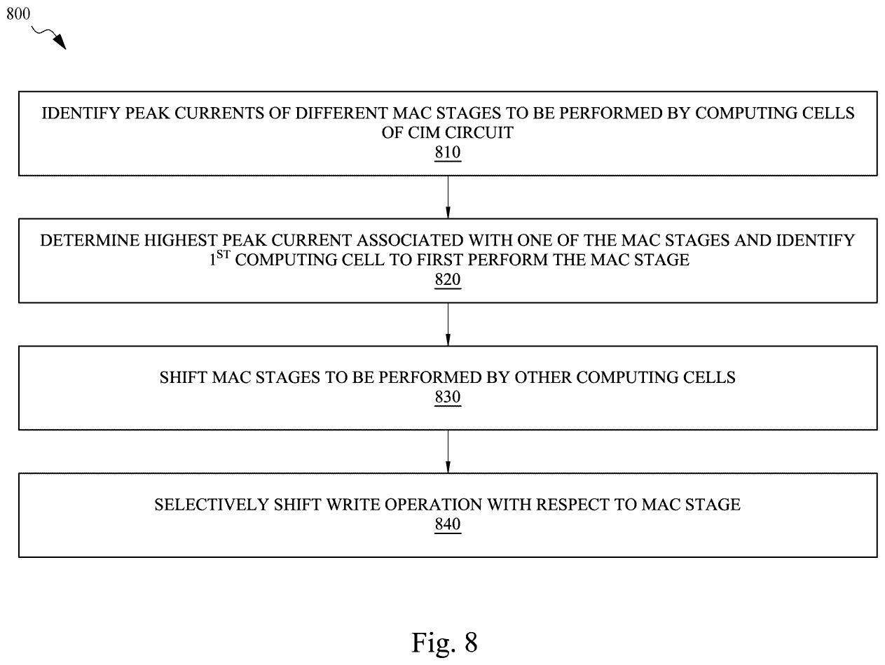

FIG. 8 illustrates a flow chart of a method 800 for scheduling MAC stages of different computing cells related to write operations, in accordance with some embodiments. The example method 800 can be performed by the CIM circuit 100 with its multiple computing cells each implemented as the computing cell 300 of FIG. 3 or the computing cell 400 of FIG. 4. As such, the following embodiment of the method 800 can be described in conjunction with but not limited to at least one of FIG. 1, 3, or 4. The illustrated embodiment of the method 800 is provided as an example and does not intent to limit the scope of the present disclosure. Therefore, it shall be understood that any of a variety of the operations of the method 800 may be omitted, re-sequenced, and/or added while remaining within the scope of the present disclosure.

The method 800 starts with operation 810 of identifying respective peak currents of different MAC stages to be performed by a plural number of computing cells of a CIM circuit. For example, the global CIM controller 110 of the CIM circuit 100 (FIG. 1) can identify the peak currents of different MAC stages 510 to 540 (FIG. 5), to be performed by each of the computing cells 120₁ to 120_{M}, as 1 mA, 2 mA, 3 mA, and 4 mA, respectively. Next, the method 800 continues to operation 820 of determining a highest peak current associated with one of the MAC stages and identifying that a first computing cell is configured to first perform this MAC stage. Continuing with the above example, the global CIM controller 110 can determine the MAC stage, associated with the highest peak current, as the MAC stage 540, and identify that the MAC stage 540 is to be first performed by the computing cell 120₁ during the clock cycle 504. Following operation 820, the method 800 continues to operation 830 of shifting MAC stages performed by other computing cells based on the MAC stage with the highest peak current performed by the first computing cell. Still with the same example, the global CIM controller 110 can shift (e.g., schedule) all the MAC stages to be performed by the computing cells 120₂, 120₃, and 120₄, respectively. Specifically, the MAC stages to be performed by the computing cells 120₂ may be shifted to start from the clock cycle 502; the MAC stages to be performed by the computing cells 120₃ may be shifted to start from the clock cycle 503; and the MAC stages to be performed by the computing cells 120₄ may be shifted to start from the clock cycle 504. The method 800 further includes operation 840 of selectively shifting (e.g., delaying) a write operation with respect to a MAC stage performed by each of the computing cells. In some embodiments, the write operation, which may be selectively delayed, can be performed by each of the computing cells in parallel with a MAC stage.

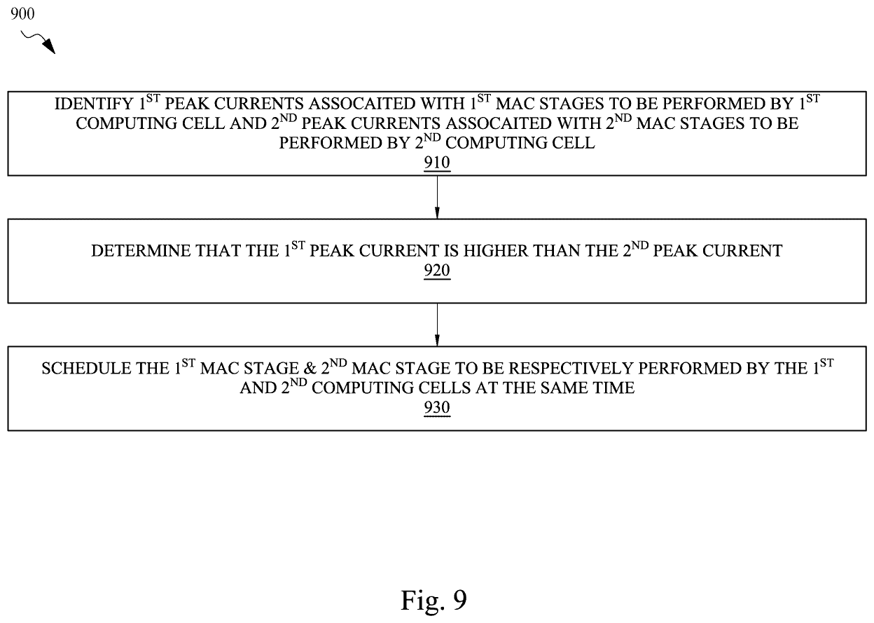

FIG. 9 illustrates a flow chart of a method 900 for scheduling MAC stages of different computing cells, in accordance with some embodiments. The example method 900 can be performed by the CIM circuit 100 including multiple computing cells 120. The illustrated embodiment of the method 900 is provided as an example and does not intent to limit the scope of the present disclosure. Therefore, it shall be understood that any of a variety of the operations of the method 900 may be omitted, re-sequenced, and/or added while remaining within the scope of the present disclosure.

The method 900 starts with operation 910 of identifying a first peak current associated with a first MAC stage to be performed by a first computing cell and a second peak current associated with a second MAC stage to be performed by a second computing cell. In some embodiments, the first computing cell can perform at least one iteration of the first MAC stage and the second MAC stage, which may form a first pipeline; and the second computing cell can perform at least one iteration of the first MAC stage and the second MAC stage, which may form a second pipeline. The method 900 continues to operation 920 of determining that the first peak current is higher than the second peak current. The method 900 continues to operation 930 of scheduling the first MAC stage and the second MAC stage to be respectively performed by the first computing cell and the second computing cell at the same time. Upon determining that the first peak current is higher than the second peak current, the first MAC stage to be performed by the first computing cell and the second MAC stage to be performed by the second computing cell may be scheduled to align with each other in the time domain. Consequently, the first pipeline and the second pipeline, configured to be performed by the first and second computing cells, respectively, may be offset in the time domain.

In one aspect of the present disclosure, a compute-in-memory (CIM) circuit is disclosed. The circuit includes a first number (M) of computing cells, wherein each of the M computing cells comprises a second number (N) of stages which, when collectively performed, are configured to provide at least one multiply-accumulate (MAC) result of a respective plurality of input data elements and a respective plurality of weight data elements. The circuit includes a global CIM controller operatively coupled to the M computing cells, and is configured to schedule a first one of the N stages of a first one of the M computing cells and a first one of the N stages of a second one of the M computing cells to be simultaneously performed, based on identifying that a first peak current previously consumed by the first stage of the first computing cell and a second peak current previously consumed by the first stage of the second computing cell are different.

In another aspect of the present disclosure, a compute-in-memory (CIM) circuit is disclosed. The circuit includes a plurality of computing cells, wherein each of the plurality of computing cells comprises a memory array and a plurality of stages, and wherein the memory array is configured to store a plurality of first data elements, and the plurality of stages, operatively coupled to the memory array, are configured to be sequentially performed to provide at least one multiply-accumulate (MAC) result of a plurality of second data elements and the plurality of first data elements. The circuit includes a global CIM controller operatively coupled to the computing cells, and is configured to shift a first one of the stages of a second one of the computing cells to align with a first one of the stages of a first one of the computing cells, based on identifying that a first peak current previously consumed by the first stage of the first computing cell is higher than a second peak current previously consumed by the first stage of the second computing cell.

In yet another aspect of the present disclosure, a method for operating a compute-in-memory (CIM) circuit is disclosed. The method includes identifying a first peak current previously consumed by a first stage to be performed by a first computing cell and a second peak current previously consumed by a second stage to be performed by a second computing cell. The method includes determining that the first peak current is higher than the second peak current. The method includes scheduling the first stage and the second stage to be respectively performed by the first computing cell and the second computing cell at the same time.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, +20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A compute-in-memory (CIM) circuit, comprising:
a first number (M) of computing cells, wherein each of the M computing cells comprises a second number (N) of stages which, when collectively performed, are configured to provide at least one multiply-accumulate (MAC) result of a respective plurality of input data elements and a respective plurality of weight data elements; and
a global CIM controller operatively coupled to the M computing cells, and is configured to schedule a first one of the N stages of a first one of the M computing cells and a first one of the N stages of a second one of the M computing cells to be simultaneously performed, based on identifying that a first peak current previously consumed by the first stage of the first computing cell and a second peak current previously consumed by the first stage of the second computing cell are different.

2. The circuit of claim 1, wherein the first peak current is higher than the second peak current.

3. The circuit of claim 1, wherein the global CIM controller is further configured to schedule the first stage of the first computing cell, the first stage of the second computing cell, and a first one of the N stages of a third one of the M computing cells to be simultaneously performed, based on identifying that the first peak current, the second peak current, and a third peak current associated with the first stage of the third computing cell are different.

4. The circuit of claim 3, wherein the first peak current is higher than any of the second peak current or the third peak current.

5. The circuit of claim 1, wherein a maximum peak current consumed by the M computing cells is equal to a sum of respective peak currents of the N stages.

6. The circuit of claim 1, wherein the N stages performed by each of the M computing cells each include one or more multiplication operations, one or more accumulation operations, one or more subtraction operations, and one or more alignment operations.

7. The circuit of claim 1, wherein each of the M computing cells further comprises a respective local CIM controller configured to schedule a write operation based on a delayed write enable signal, the write operation including writing the respective weight data elements into a respective memory array.

8. The circuit of claim 7, wherein each of the M computing cells is configured to simultaneously perform one of its N stages and the write operation, based on the delayed write enable signal.

9. The circuit of claim 7, wherein each of the M computing cells comprises a delay chain and one or mode logic gates, which are collectively configured to generate the delayed write enable signal.

10. The circuit of claim 9, wherein each of the M computing cells is configured to receive a clock signal, a MAC enable signal, and a write enable signal for generating the delayed write enable signal.

11. A compute-in-memory (CIM) circuit, comprising:
a plurality of computing cells, wherein each of the plurality of computing cells comprises a memory array and a plurality of stages, and wherein the memory array is configured to store a plurality of first data elements, and the plurality of stages, operatively coupled to the memory array, are configured to be sequentially performed to provide at least one multiply-accumulate (MAC) result of a plurality of second data elements and the plurality of first data elements; and
a global CIM controller operatively coupled to the computing cells, and is configured to shift a first one of the stages of a second one of the computing cells to align with a first one of the stages of a first one of the computing cells, based on identifying that a first peak current previously consumed by the first stage of the first computing cell is higher than a second peak current previously consumed by the first stage of the second computing cell.

12. The circuit of claim 11, the global CIM controller is further configured to shift a first one of the stages of a third one of the computing cells to align with the first stage of the first computing cell, based on identifying that the first peak current is higher than any of the second peak current or a third peak current associated with the first stage of the third computing cell.

13. The circuit of claim 11, wherein the stages each include one or more multiplication operations, one or more accumulation operations, one or more subtraction operations, and one or more alignment operations.

14. The circuit of claim 11, wherein each of the computing cells further comprises a respective local CIM controller configured to schedule a write operation based on a delayed write enable signal, the write operation including writing the respective first data elements into the respective memory array.

15. The circuit of claim 14, wherein each of the computing cells is configured to simultaneously perform one of its stages and the write operation, based on the delayed write enable signal.

16. The circuit of claim 14, wherein each of the computing cells comprises a delay chain and one or mode logic gates, which are collectively configured to generate the delayed write enable signal.

17. The circuit of claim 14, wherein each of the computing cells is configured to receive a clock signal, a MAC enable signal, and a write enable signal for generating the delayed write enable signal.

18. A method for operating a compute-in-memory (CIM) circuit, comprising:
identifying a first peak current previously consumed by a first stage to be performed by a first computing cell and a second peak current previously consumed by a second stage to be performed by a second computing cell;
determining that the first peak current is higher than the second peak current; and
scheduling the first stage and the second stage to be respectively performed by the first computing cell and the second computing cell at the same time.

19. The method of claim 18, wherein the first stage and the second stage each include one or more multiplication operations, one or more accumulation operations, one or more subtraction operations, and one or more alignment operations.

20. The method of claim 18, further comprising:
generating a first partial multiply-accumulate (MAC) result by performing a plurality of the first stages; and
generating a second partial MAC result by performing a plurality of the second stages.
